(19) United States
(12) Patent Application Publication
(10) Pub. No.: US 2025/0393197 A1
(43) Pub. Date: Dec. 25, 2025

(54) SEMICONDUCTOR STRUCTURE AND METHOD OF FORMING THE SAME

(71) Applicant: Winbond Electronics Corp., Taichung CIty (TW)

(72) Inventor: Yi-Chi TSAI, Tainan City (TW)

(21) Appl. No.: 19/040,044

(22) Filed: Jan. 29, 2025

(30) Foreign Application Priority Data
Jun. 19, 2024 (TW) 113122670

(51) Int. Cl. H10B 12/00

(52) U.S. Cl. CPC H10B 12/482; H10B 12/02; H10B 12/485

(57) ABSTRACT

A semiconductor structure and a method of forming the same are provided. The semiconductor structure includes a substrate, a bit line structure, a first liner, and a first air gap. The bit line structure is disposed on the substrate and has a first side surface and a second side surface. The second side surface is opposite the first side surface. The first liner is disposed on the bit line structure and includes a first sub-liner and a second sub-liner. The first sub-liner is disposed on the first side surface. The second sub-liner is disposed on the second side surface. The first air gap is disposed on the first sub-liner, and the bottom surface of the first air gap is lower than the bottom surface of the bit line structure.

### CROSS REFERENCE TO RELATED APPLICATIONS

This Application claims priority of Taiwan Patent Application No. 113122670, filed on Jun. 19, 2024, the entirety of which is incorporated by reference herein.

### BACKGROUND

### Technical Field

The present invention relates to a semiconductor structure and a method of forming the same, and, in particular, it relates to the semiconductor structure having an air gap and a method of forming the same.

### Description of the Related Art

With the trend of miniaturization of semiconductor devices, the size of memory also continues to shrink to increase integration and to improve performance. However, this continuous reduction in size makes the storage capacitance of the component too small and the bit line capacitance too large, which adversely affects the performance of the semiconductor device.

### BRIEF SUMMARY

In view of the above problems, the present disclosure reduces the parasitic capacitance adjacent to the bit line structure by disposing an air gap with a low dielectric constant on the bit line structure. That is, by reducing the parasitic capacitance caused by coupling between a conductive element in the bit line structure and other elements, the electrical characteristics of the semiconductor structure are improved.

An embodiment of the present invention provides a semiconductor structure. The semiconductor structure includes a substrate, a bit line structure, a first liner, and a first air gap. The bit line structure is disposed on the substrate and has a first side surface and a second side surface opposite to the first side surface. The first liner is disposed on the bit line structure and includes a first sub-liner and a second sub-liner. The first sub-liner is disposed on the first side surface. The second sub-liner is disposed on the second side surface. The first air gap is disposed on the first sub-liner, and the bottom surface of the first air gap is lower than the bottom surface of the bit line structure.

An embodiment of the present invention provides a method of forming a semiconductor device. The method includes providing a substrate. A bit line structure is formed on the substrate, wherein the bit line structure has a first side surface and a second side surface opposite to the first side surface. A first liner is formed on the bit line structure. A first conductive pillar is formed on the substrate, wherein the first conductive pillar is adjacent to the bit line structure. A dielectric layer is formed on the first conductive pillar. A protective layer is formed on the dielectric layer to form a first air gap on the first side surface of the bit line structure.

### BRIEF DESCRIPTION OF THE DRAWINGS

FIGS. 1 to 17 show cross-sectional schematic diagrams of semiconductor structures at various stages of a formation method according to some embodiments, respectively.

FIGS. 18 to 20 and FIGS. 22 to 23 show cross-sectional schematic diagrams of semiconductor structures at various stages of a formation method according to some embodiments, respectively.

FIG. 21 shows a schematic top view of a semiconductor structure according to some embodiments.

### DETAILED DESCRIPTION

In the present disclosure, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other. For convenience of description, hereinafter, the X-axis direction is the first direction D1 (width direction), the Y-axis direction is the second direction D2 (length direction), and the

Z-axis direction is the third direction D3 (height or thickness direction). In some embodiments, the schematic cross-sectional views described herein are schematic views of the XZ plane, and the schematic top view described herein is schematic views of the XY plane. In some embodiments, the normal direction of the substrate 100 is the third direction D3. The schematic cross-sectional views described herein are schematic cross-sectional views taken along the direction perpendicular to the extending direction of the bit lines of the semiconductor structure (parallel to the extending direction of the word lines of the semiconductor structure).

Referring to FIG. 1, a substrate 100 is provided. The substrate 100 may be a wafer such as a silicon wafer, a semiconductor-on-insulator substrate, or a bulk semiconductor substrate.

In some embodiments, an isolation structure (not shown) is formed in the substrate 100 to define the active area AA. The isolation structure may include an oxide such as silicon oxide. The isolation structure may be formed by an etching process and a deposition process.

In some embodiments, after the formation of the active area AA, a word line structure WLS may be formed in the substrate 100. The word line structure WLS may be a buried word line structure, so the top surface of the word line structure WLS may be lower than the top surface of the substrate 100. The word line structure WLS may extend along the first direction D1.

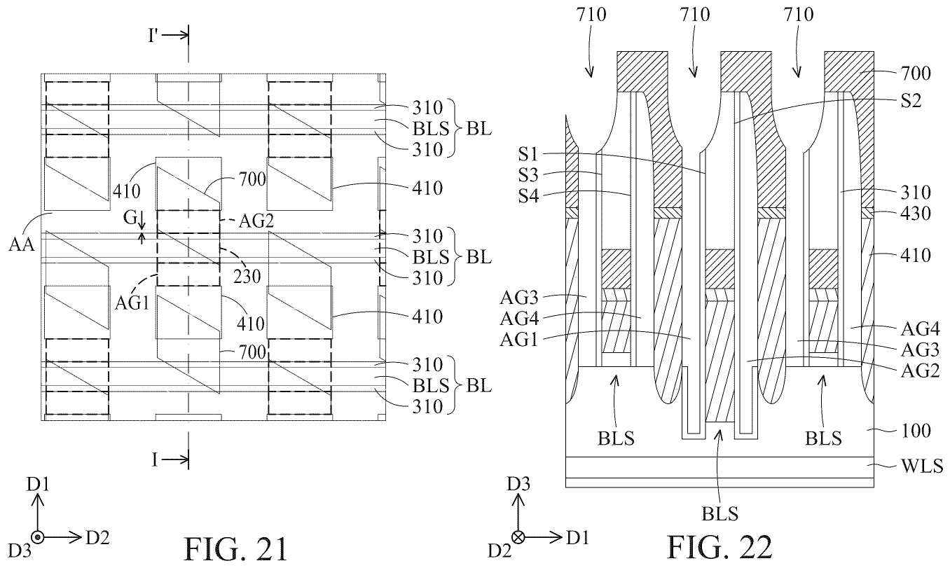

As shown in FIG. 1, a plurality of bit line structures BLS may be formed on the substrate 100 and on the word line structure WLS. The bit line structure BLS may include a bit line dielectric layer 210, a gate contact 220, a bit line contact 230, an interlayer 240, a bit line conductive layer 250, and a mask layer 260. The bit line structure BLS may be formed in the etching process and the deposition process. In some embodiments, the bit line contact 230 may be disposed on the substrate 100, the bit line conductive layer 250 may be disposed on the bit line contact 230, and the mask layer 260 may be disposed on the bit line conductive layer 250. In some embodiments, the bit line structure BLS and the liner subsequently formed on the bit line structure BLS may serve as a bit line in the semiconductor structure (such as the bit line BL shown in FIG. 21).

In some embodiments, the bit line dielectric layer 210 may be formed on the substrate 100, and the bit line dielectric layer 210 may serve as a gate dielectric layer. The gate contact 220 may be formed on bit line dielectric layer 210. A trench (not shown) may be formed in the gate contact 220 and the bit line dielectric layer 210 to define the subsequently formed bit line contact. The bit line contact 230 may be formed in the trench, and the bit line contact 230 may serve as an array of contacts. The interlayer 240 may be formed on the gate contact 220 and the bit line contact 230 to improve the compatibility between the gate contact 220 and the bit line contact 230 and other layers. In other embodiments, the interlayer 240 may be omitted. The bit line conductive layer 250 may be formed on the interlayer 240. The mask layer 260 may be formed on the bit line conductive layer 250. Next, a patterning process is performed on the bit line dielectric layer 210, the gate contact 220, the bit line contact 230, the interlayer 240, the bit line conductive layer 250, and the mask layer 260 to form a bit line structure BLS on the substrate 100.

In some embodiments, the bit line dielectric layer 210 and the mask layer 260 may include oxides such as silicon oxide, nitrides such as silicon nitride, oxynitrides such as silicon oxynitride, oxycarbide such as silicon oxycarbide, the like, or a combination thereof. For example, the bit line dielectric layer 210 may include silicon oxide, and the mask layer 260 may include silicon nitride. In some embodiments, the gate contact 220, the bit line contact 230, the interlayer 240, and the bit line conductive layer 250 may include conductive materials. For example, the conductive materials may include metals, metal nitrides, semiconductor materials, the like, or a combination thereof. In some embodiments, the metal may include gold, nickel, platinum, palladium, iridium, titanium, chromium, tungsten, aluminum, copper, the like, or a combination thereof. In some embodiments, the metal nitride may include titanium nitride, molybdenum nitride, tungsten nitride, tantalum nitride, the like, or a combination thereof. The semiconductor material may include polycrystalline silicon or polycrystalline germanium. For example, the gate contact 220 may include polycrystalline silicon, the bit line contact 230 may include polycrystalline silicon, the interlayer 240 may include titanium nitride, and the bit line conductive layer 250 may include tungsten.

In some embodiments, the bit line structure BLS including the bit line contact 230 may have a first side surface S1 and a second side surface S2 which is opposite the first side surface S1. In some embodiments, the bit line structure BLS including the gate contact 220 may have a third side surface S3 and a fourth side surface S4 which is opposite the third side surface S3.

As shown in FIG. 1, a first liner 310 may be formed on the bit line structure BLS, and a second liner 320 may be formed on the first liner 310. In some embodiments, the first liner 310 may be conformally formed on the substrate 100 and the bit line structure BLS, and the second liner 320 may be conformally formed on the first liner 310. Next, a portion of the first liner 310 and a portion of the second liner 320 may be removed to expose the top surface of the bit line structure BLS. Therefore, the top surface of the bit line structure BLS, the top surface of the first liner 310, and the top surface of the second liner 320 may be coplanar (aligned with each other). The materials and formation methods of the first liner 310 and the second liner 320 may be the same as or different from that of the bit line dielectric layer 210. For example, the first liner 310 may include silicon carbonitride or silicon oxycarbide, and the second liner 320 may include silicon oxide. In some embodiments, after removal of the portion of the first liner 310 and the portion of the second liner 320, the first liner 310 may include a first sub-liner 311, a second sub-liner 312, a third sub-liner 313, and a fourth sub-liner 314. In some embodiments, the first sub-liner 311 may be disposed on the first side surface S1, the second sub-liner 312 may be disposed on the second side surface S2, and the third sub-liner 313 may be disposed on the third side surface S3, and the fourth sub-liner 314 may be disposed on the fourth side surface S4.

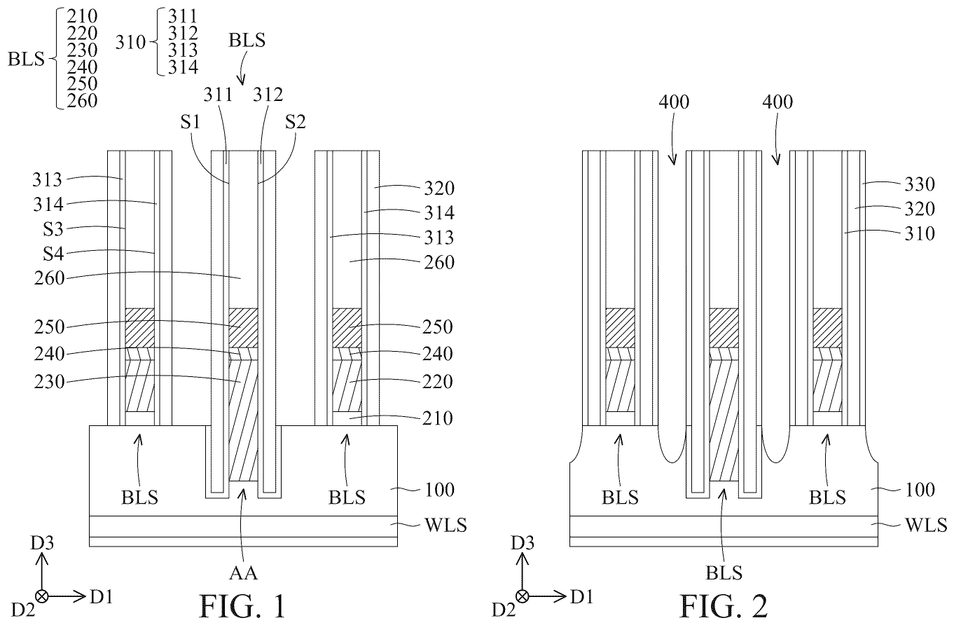

Referring to FIG. 2, a third liner 330 may be formed on the second liner 320. The material and formation method of the third liner 330 may be the same as or different from that of the bit line dielectric layer 210. For example, the third liner 330 may include silicon nitride. In some embodiments, the third liner 330 may be conformally formed on the second liner 320. Next, a portion of the third liner 330 may be removed to make the top surface of the third liner 330 align with the top surface of the second liner 320 and form a first trench 400 between the bit line structures BLS. The bottom surface of the first trench 400 may be lower than the top surface of the substrate 100. The first trench 400 may be used to define a subsequently formed first conductive pillar.

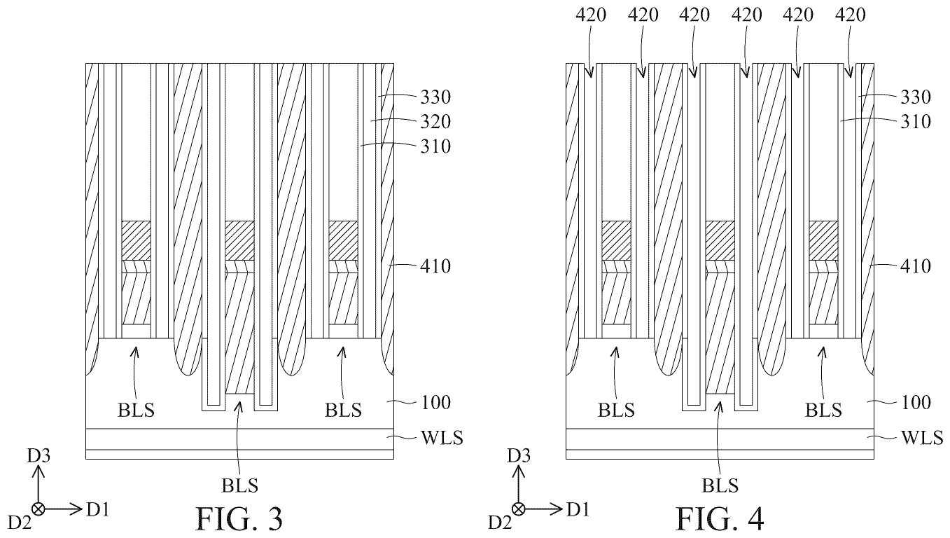

Referring to FIG. 3, a first conductive pillar 410 is formed on the substrate 100 and in the first trench 400. The first conductive pillar 410 may be adjacent to the bit line structure BLS. The first conductive pillar 410 may be formed on the third liner 330 and in directly contact with the third liner 330. In some embodiments, the material of the first conductive pillar 410 may be blanketly formed on the bit line structure BLS and the substrate 100. Then, the material of the first conductive pillar 410 may be planarized, so that the top surface of the first conductive pillar 410 is aligned with the top surface of the bit line structure BLS. The planarized first conductive pillar 410 may expose the top surface of the first liner 310, the top surface of the second liner 320, and the top surface of the third liner 330. The first conductive pillar 410 may serve as a storage node contact (NC).

Referring to FIG. 4, after the formation of the first conductive pillar 410, the second liner 320 may be removed to form a second trench 420 between the first liner 310 and the third liner 330. After the removal of the second liner 320, the first liner 310 and the third liner 330 located on the bit line structure BLS may be remained. The second liner 320 may be removed by a wet etching process such as a dilute hydrofluoric acid (DHF) cleaning process. Compared with the etching rates of the first liner 310, the third liner 330, and the first conductive pillar 410, the etching rate of the second liner 320 by the wet etchant is significantly larger.

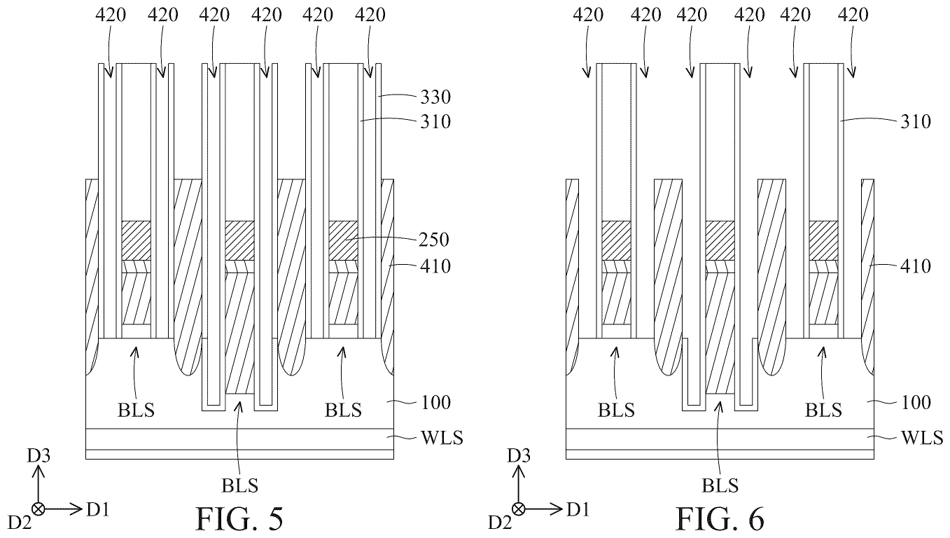

Referring to FIG. 5, after the removal of the second liner 320, the first conductive pillar 410 may be etched back so that the top surface of the first conductive pillar 410 may be lower than the top surface of the bit line structure BLS. The top surface of the first conductive pillar 410 may be higher than the top surface of the bit line conductive layer 250.

Referring to FIG. 6, after the first conductive pillar 410 is etched back, the third liner 330 may be removed, and the first liner 310 may be remained on the bit line structure BLS. The materials of the third liner 330 and the first liner 310 have etching selectivity, so the third liner 330 may be removed by a wet etching process such as a phosphoric acid cleaning process. The removal of the third liner 330 may expose the side surface of the first conductive pillar 410.

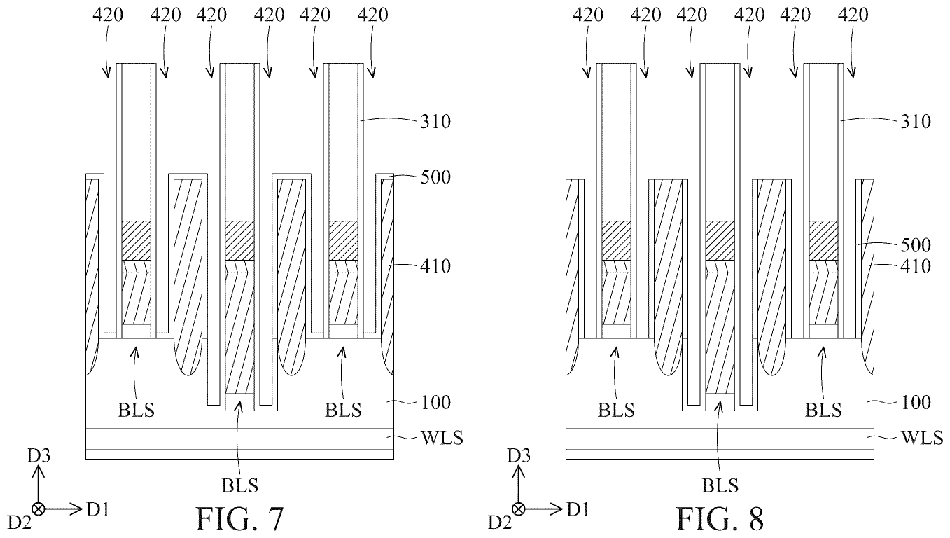

Referring to FIG. 7, a heat treatment process may be performed on the first conductive pillar 410 to form a dielectric layer 500 on the exposed surface of the first conductive pillar 410. The dielectric layer 500 may be formed on the top surface and the side surface of the first conductive pillar 410. Therefore, the first conductive pillar 410 may be protected by the dielectric layer 500, so that the first conductive pillar 410 may not be damaged by other steps in the method of forming the semiconductor structure. For example, the heat treatment process may be an in-situ-steam-generation-process (ISSG), but the present disclosure is not limited thereto. The dielectric layer 500 may be formed by oxidizing a portion of the first conductive pillar 410, and thus the dielectric layer 500 may include silicon oxide formed by polycrystalline silicon.

Referring to FIG. 8, a portion of the dielectric layer 500 may be removed (etched back) to expose the top surface of the first conductive pillar 410 to facilitate electrical connection between the first conductive pillar 410 and the subsequently formed second conductive pillar.

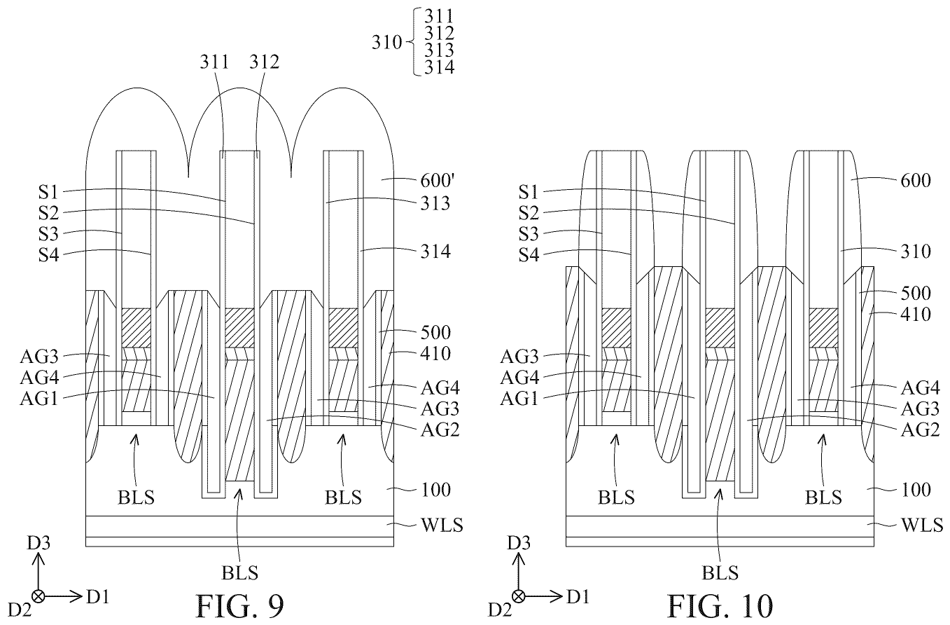

Referring to FIG. 9, a protective material 600′ may be formed on the bit line structure BLS, the first liner 310, the first conductive pillar 410, and the dielectric layer 500. In some embodiments, the profile of the protective material 600′ in the cross-sectional view may be adjusted by selecting types of the protective material 600′ with different step coverages. For example, when a material is deposited on a component, the ratio of a first thickness of the material on the side surface of the component to a second thickness of the material on the top surface of the component (the first thickness/the second thickness) may be referred as a step coverage. In some embodiments, the step coverage of the protective material 600′ may be less than 1, thereby having a lower step coverage. Accordingly, when the step coverage of the protective material 600′ is low, the protective material 600′ will not (completely) fill the second trench 420, so an air gap may be formed below the protective material 600′. In some embodiments, the first air gap AG1, the second air gap AG2, the third air gap AG3, and the fourth air gap AG4 may be respectively formed below the protective material 600′. In some embodiments, the protective material 600′ may include an oxide such as silicon oxide, a nitride such as silicon nitride, an oxynitride such as silicon oxynitride, an oxycarbide such as silicon oxycarbide, the like, or a combination thereof, but the present disclosure is not limited thereto. For example, the protective material 600′ may include p-type doped silicon oxide, and the silicon oxide may be formed by tetraethoxysilane (TEOS). Accordingly, the step coverage of the protective material 600′ may be adjusted by using different dopant types and doping concentrations.

In some embodiments, the first air gap AG1 and the second air gap AG2 may be respectively formed on the first side surface S1 and the second side surface S2 of the bit line structure BLS. Similarly, the third air gap AG3 and the fourth air gap AG4 may be respectively formed on the third side surface S3 and the fourth side surface S4. The first air gap AG1, the second air gap AG2, the third air gap AG3, and/or the fourth air gap AG4 may include air, an inert gas such as helium, argon, other suitable gases, or a combination thereof, or may be substantially vacuum.

Referring to FIG. 10, the protective material 600′ may be removed to expose the top surface of the first conductive pillar 410 so as to form a protective layer 600 on the dielectric layer 500. A portion of the protective material 600′ may be removed, and another portion of the protective material 600′ remains as a protective layer 600 on the upper portion of the bit line structure BLS. The exposed top surface of the first conductive pillar 410 facilitates electrical connection between the first conductive pillar 410 and the subsequently formed second conductive pillar. After the removal of the protective material 600′, the top surface of the bit line structure BLS may be exposed. The top surface of the bit line structure BLS may be aligned with the top surface of the protective layer 600. The protective layer 600 and the bit line structure BLS may have a bullet-shaped profile.

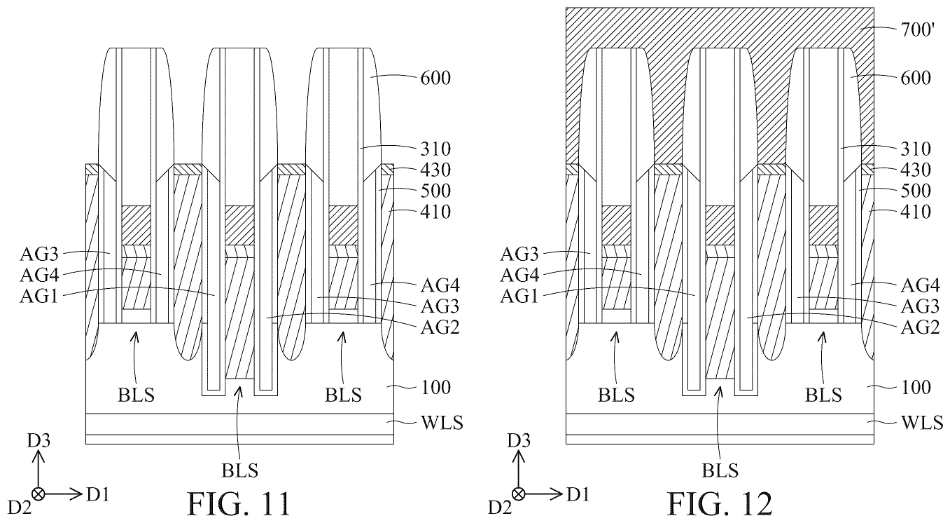

Referring to FIG. 11, a silicide layer 430 may be formed on the exposed surface of the first conductive pillar 410 to reduce resistance, thereby forming an ohmic contact. For example, the silicide layer 430 may include cobalt silicide.

Referring to FIG. 12, a conductive material 700′ may be blanketly formed on the bit line structure BLS, the first liner 310, and the protective layer 600. The conductive material 700′ may include the aforementioned conductive materials. For example, the conductive material 700′ may include tungsten.

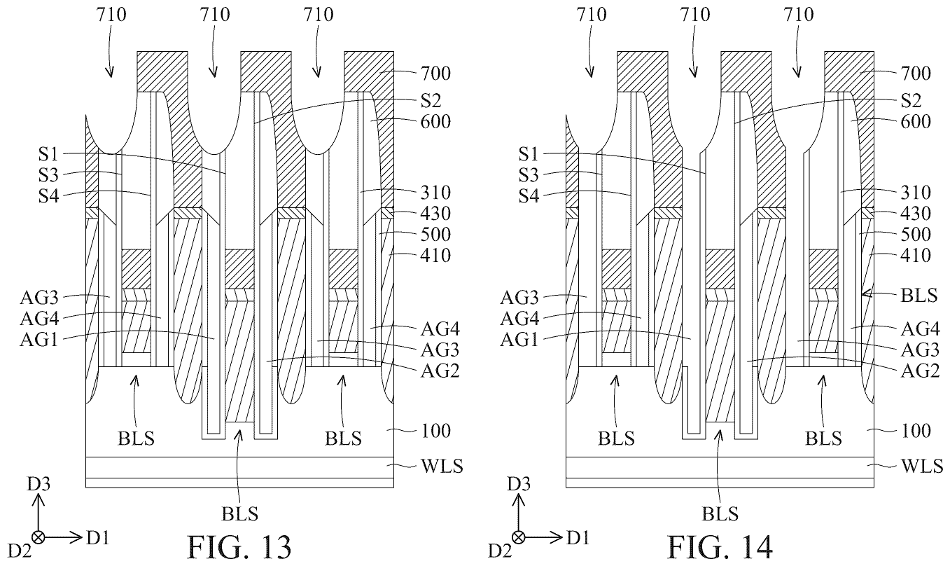

Referring to FIG. 13, a portion of the conductive material 700′, a portion of the bit line structure BLS, a portion of the first liner 310, and a portion of the protective layer 600 may be removed to form an opening 710 in the conductive material 700′, thereby forming a second conductive pillar 700 on the first conductive pillar 410. The silicide layer 430 may be between the first conductive pillar 410 and the second conductive pillar 700. In some embodiments, the opening 710 may expose the upper portion of the bit line structure BLS, and expose the first liner 310 and the protective layer 600 on the first side surface S1 and the third side surface S3. The second conductive pillar 700 may cover the second side surface S2 and the fourth side surface S4 of the bit line structure BLS. In other words, the opening 710 may substantially not expose the second side surface S2 and the fourth side surface S4 of the bit line structure BLS. Accordingly, the conductive material 700′ may be separated by the opening 710 to form the second conductive pillars 700 that are electrically isolated from each other on the first conductive pillar 410. The second conductive pillar 700 may serve as a landing pad (CF). In some embodiments, further processes may be performed to form a storage node on the second conductive pillar 700, wherein the storage node serves as a capacitor.

In other embodiments, the location where the opening 710 is formed may be adjusted. For example, the opening 710 may expose the upper portion of the bit line structure BLS, and expose the first liner 310 and the protective layer 600 on the second side surface S2 and the fourth side surface S4. In this embodiment, the second conductive pillar 700 may cover the first side surface S1 and the third side surface S3 of the bit line structure BLS. In other words, in this embodiment, the opening 710 may substantially not expose the first side surface S1 and the third side surface S3 of the bit line structure BLS.

Referring to FIG. 14, the protective layer 600 on the first side surface S1 and the third side surface S3 may be removed by passing the etchant through the opening 710 by a wet etching process such as a dilute hydrofluoric acid cleaning process. Next, the etchant removes the dielectric layer 500 on the first side surface S1 and the third side surface S3. In some embodiments, the removal of the protective layer 600 and the removal of the dielectric layer 500 may be performed in the same process or in different processes. After the removal of the protective layer 600 and the dielectric layer 500 on the first side surface S1 and the third side surface S3, the first air gap AG1 and the third air gap AG3 may be damaged and be in fluid connected with the opening 710.

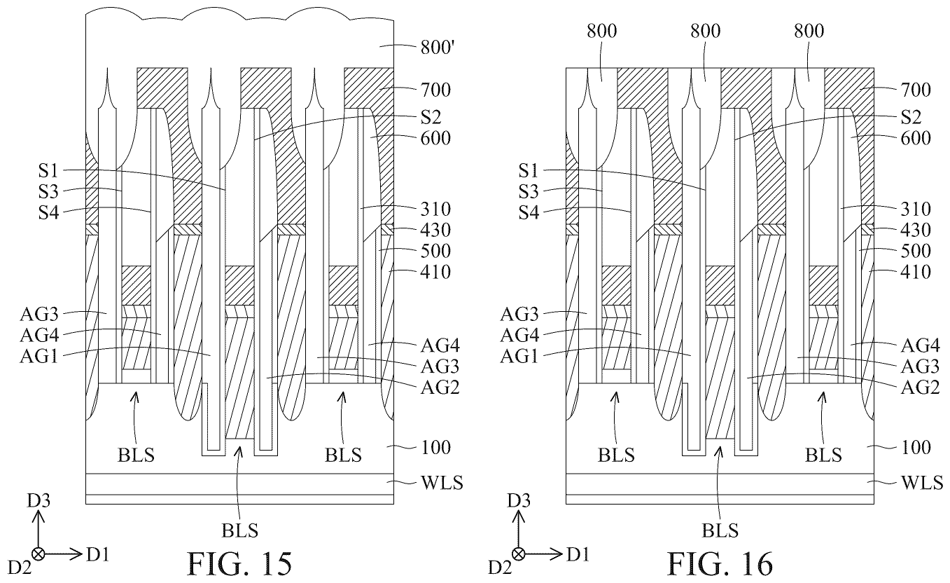

Referring to FIG. 15, a capping material 800′ may be formed on the second conductive pillar 700, the bit line structure BLS, the first liner 310, and the opening 710. In some embodiments, the profile of the capping material 800′ may be adjusted by selecting types of the capping material 800′ with different step coverages. In some embodiments, the step coverage of the capping material 800′ may be less than 1, thereby having a lower step coverage. Accordingly, when the step coverage of the capping material 800′ is low, the capping material 800′ will not (completely) fill the opening 710. Therefore, the capping material 800′ may re-cap the first air gap AG1 and the third air gap AG3 that are in fluid connected with the opening 710, and may re-form the first air gap AG1 and the third air gap AG3 below the capping material 800′. The capping material 800′ may be the same as or different from the protective material 600′. For example, the capping material 800′ may include silicon oxide. The first air gap AG1 may be formed on the first side surface S1 of the bit line structure BLS, and the third air gap AG3 may be formed on the third side surface S3. After re-capping, the first air gap AG1 and/or the third air gap AG3 may include air, an inert gas such as helium, argon, other suitable gases, or a combination thereof, or may be substantially vacuum.

Referring to FIG. 16, the capping material 800′ may be planarized to expose the top surface of the second conductive pillar 700 so as to form the capping layer 800 on the second conductive pillar 700, the first liner 310, and the bit line structure BLS. The top surface of the capping layer 800 may be aligned with the top surface of the second conductive pillar 700. The bottom surface of the capping layer 800 may be spaced apart from the substrate 100. The capping layer 800 may not be in contact with the substrate 100. The bottom surface of the capping layer 800 may be lower than the top surface of the bit line structure BLS. The bottom surface of the capping layer 800 may be higher than the top surface of the first conductive pillar 410.

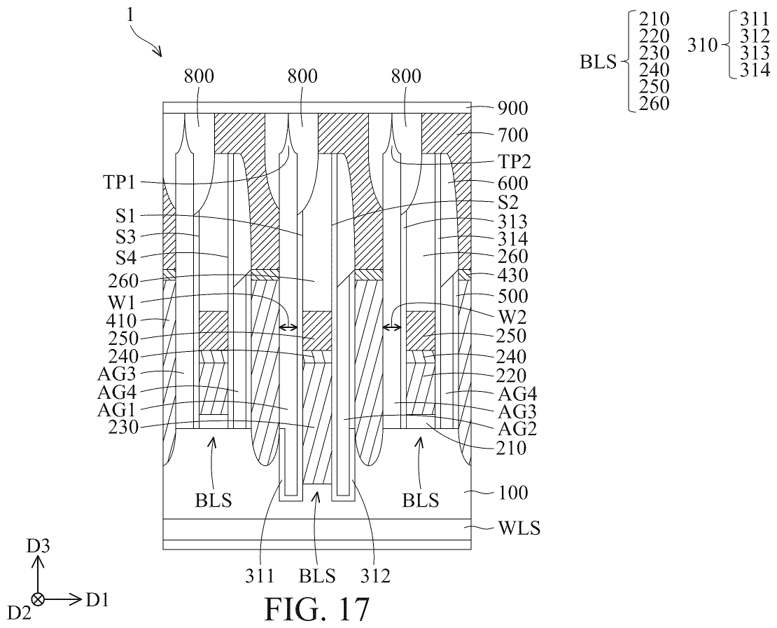

Referring to FIG. 17, in some embodiments, a planarization layer 900 may be formed on the second conductive pillar 700 and the capping layer 800 so as to form the semiconductor structure 1. The material and formation method of the planarization layer 900 may be the same as or different from that of the bit line dielectric layer 210. For example, the planarization layer 900 may include silicon nitride.

As shown in FIG. 17, the first air gap AG1 may be disposed on the first sub-liner 311 of the first liner 310. The bottom surface of the first air gap AG1 may be lower than the bottom surface of the bit line contact 230 of the bit line structure BLS. The bottom surface of the first air gap AG1 may be lower than the top surface of the substrate 100. The top surface of the first air gap AG1 may be higher than the top surface of the first conductive pillar 410. The top surface of the first air gap AG1 may be higher than the top surface of the mask layer 260 of the bit line structure BLS. The first air gap AG1 may be in directly contact with the first conductive pillar 410, the silicide layer 430, and the second conductive pillar 700. The first sub-liner 311 of the first liner 310, the first conductive pillar 410, the silicide layer 430, the second conductive pillar 700, and the capping layer 800 may surround the first air gap AG1. In other words, the space formed by the first sub-liner 311 of the first liner 310, the first conductive pillar 410, the silicide layer 430, the second conductive pillar 700, and the capping layer 800 is the first air gap AG1.

As shown in FIG. 17, in the first direction D1, the first air gap AG1 may have a width W1, and the width W1 may decrease along the normal direction of the substrate 100 (that is, the third direction D3). For example, the width W1 may decrease gradually, stepwise, or linearly along the normal direction of the substrate 100. As shown in FIG. 17, the first air gap AG1 may have a tip portion TP, and the shape of the tip portion TP may correspond to the shape of the bottom surface of the capping layer 800. Therefore, the shape of the tip portion TP may be adjusted by changing the step coverage of the capping material 800′. Accordingly, by disposing the first air gap AG1 on the first side surface S1 of the bit line structure BLS, the parasitic capacitance adjacent to the first side surface S1 of the bit line structure BLS is reduced.

As shown in FIG. 17, the second air gap AG2 may be disposed on the second sub-liner 312 of the first liner 310. The bottom surface of the second air gap AG2 may be lower than the bottom surface of the bit line contact 230 of the bit line structure BLS. The bottom surface of the second air gap AG2 may be lower than the top surface of the substrate 100. The top surface of the second air gap AG2 may be lower than the top surface of the bit line structure BLS. The top surface of the second air gap AG2 may be lower than the top surface of the first air gap AG1. The top surface of the second air gap AG2 may be between the top surface of the bit line conductive layer 250 of the bit line structure BLS and the bottom surface of the silicide layer 430. The second air gap AG2 may be between the second sub-liner 312 and the dielectric layer 500. The second sub-liner 312, the dielectric layer 500, and the protective layer 600 may surround the second air gap AG2. The dielectric layer 500 may be adjacent to the second air gap AG2. The dielectric layer 500 may be disposed between the second air gap AG2 and the first conductive pillar 410. The protective layer 600 may be disposed between the second sub-liner 312 and the second conductive pillar 700. Accordingly, by disposing the second air gap AG2 on the second side surface S2 of the bit line structure BLS, the parasitic capacitance adjacent to the second side surface S2 of the bit line structure BLS is reduced.

As shown in FIG. 17, the third air gap AG3 may be disposed on the third sub-liner 313 of the first liner 310. The bottom surface of the third air gap AG3 may be aligned with the bottom surface of the bit line structure BLS. The bottom surface of the third air gap AG3 may be aligned with the bottom surface of the bit line dielectric layer 210. The top surface of the third air gap AG3 may be higher than the top surface of the bit line structure BLS. The top surface of the third air gap AG3 may be higher than the top surface of the first conductive pillar 410. The third air gap AG3 may be between the gate contact 220 and the first conductive pillar 410. In the first direction D1, the third air gap AG3 may have a width W2, and the width W2 decreases along the normal direction of the substrate 100 (that is, the third direction D3). The third air gap AG3 may have a tip portion TP2. Accordingly, by disposing the third air gap AG3 on the third side surface S3 of the bit line structure BLS, the parasitic capacitance adjacent to the third side surface S3 of the bit line structure BLS is reduced.

As shown in FIG. 17, the fourth air gap AG4 may be disposed on the fourth sub-liner 314 of the first liner 310. The bottom surface of the fourth air gap AG4 may be aligned with the bottom surface of the bit line structure BLS. The bottom surface of the fourth air gap AG4 may be aligned with the bottom surface of the bit line dielectric layer 210. The top surface of the fourth air gap AG4 may be lower than the top surface of the third air gap AG3. The fourth air gap AG4 may be between the gate contact 220 and the first conductive pillar 410. Accordingly, by disposing the fourth air gap AG4 on the fourth side surface S4 of the bit line structure BLS, the parasitic capacitance adjacent to the fourth side surface S4 of the bit line structure BLS is reduced.

As shown in FIG. 17, the present disclosure may reduce the parasitic capacitance between the bit line structure BLS and the second conductive pillar 700 or the first conductive pillar 410. In addition, on opposite sides of the same bit line structure BLS, the parasitic capacitances between the bit line structure BLS and other components may be the same or different. For example, the bit line structure BLS including the bit line contact 230 may be between the first air gap AG1 and the second air gap AG2. The equivalent dielectric constant of the first sub-liner 311 and the first air gap AG1 located on the first side surface S1 of the bit line structure BLS may be smaller than the equivalent dielectric constant of the second sub-liner 312, the second air gap AG2, and the protective layer 600 located on the second side surface S2 of the bit line structure BLS. Therefore, the parasitic capacitance between the first side surface S1 of the bit line structure BLS and the second conductive pillar 700 and the first conductive pillar 410 may be smaller than the parasitic capacitance between the second side surface S2 of the bit line structure BLS and the second conductive pillar 700 and the first conductive pillar 410. Therefore, the sensing margin of the subsequently formed memory device may be increased.

For example, the bit line structure BLS including the gate contact 220 may be between the third air gap AG3 and the fourth air gap AG4. The equivalent dielectric constant of the third sub-liner 313 and the third air gap AG3 located on the third side surface S3 of the bit line structure BLS may be smaller than the equivalent dielectric constant of the fourth sub-liner 314, the fourth air gap AG4, and the protective layer 600 located on the fourth side surface S4 of the bit line structure BLS. Therefore, the parasitic capacitance between the third side surface S3 of the bit line structure BLS and the second conductive pillar 700 and the first conductive pillar 410 may be smaller than the parasitic capacitance between the fourth side surface S4 of the bit line structure BLS and the second conductive pillar 700 and the first conductive pillar 410. Thus, the voltage difference and sensing margin of the subsequently formed memory device may be increased. Accordingly, the bit line structure BLS may have asymmetric air gaps, asymmetric equivalent dielectric constants, and asymmetric parasitic capacitances on different side surfaces.

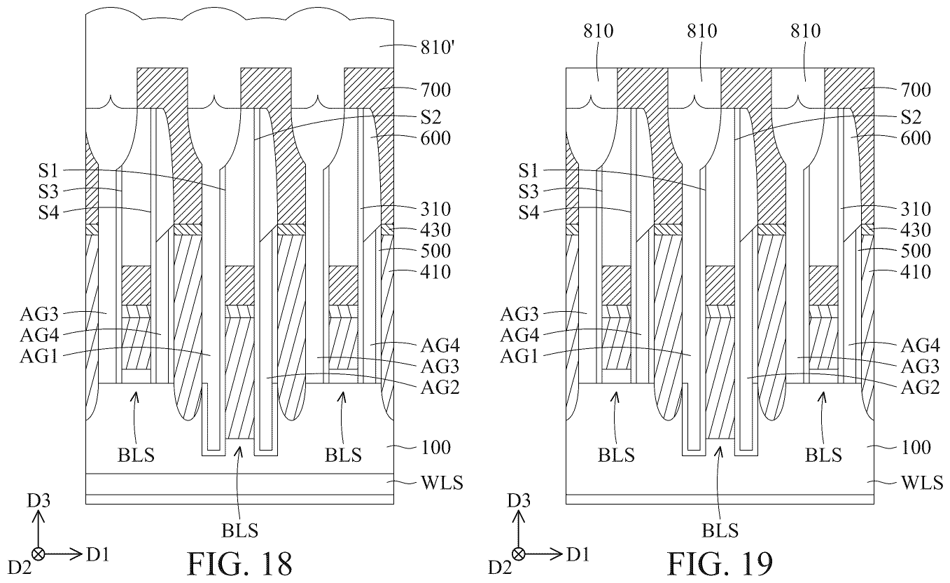

Referring to FIG. 18, in other embodiments, FIG. 18 may be continued from FIG. 14 to form a capping material 810′ on the second conductive pillar 700. The capping material 810′ may be not in contact with the first liner 310. For example, the capping material 810′ may include silicon nitride.

Referring to FIG. 19, the capping material 810′ may be planarized to expose the top surface of the second conductive pillar 700, so as to form the capping layer 810 on the side surface of the second conductive pillar 700. The top surface of the capping layer 810 may be aligned with the top surface of the second conductive pillar 700. The capping layer 810 may be spaced apart from the substrate 100. The bottom surface of the capping layer 810 may be higher than or aligned with the top surface of the bit line structure BLS.

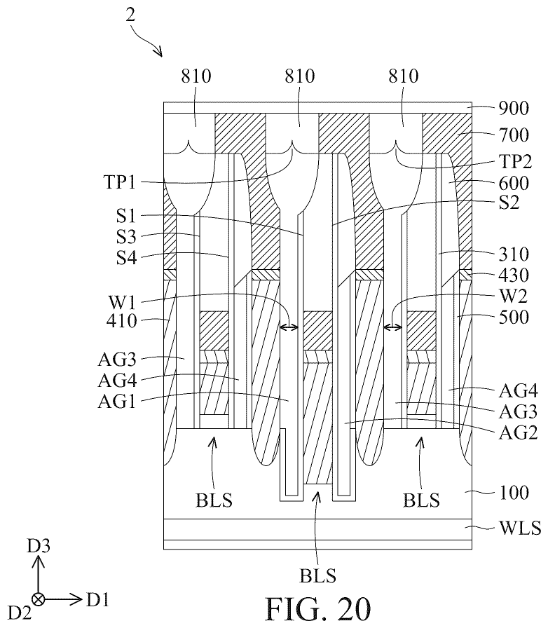

Referring to FIG. 20, the planarization layer 900 may be formed on the second conductive pillar 700 and the capping layer 810 to form the semiconductor structure 2.

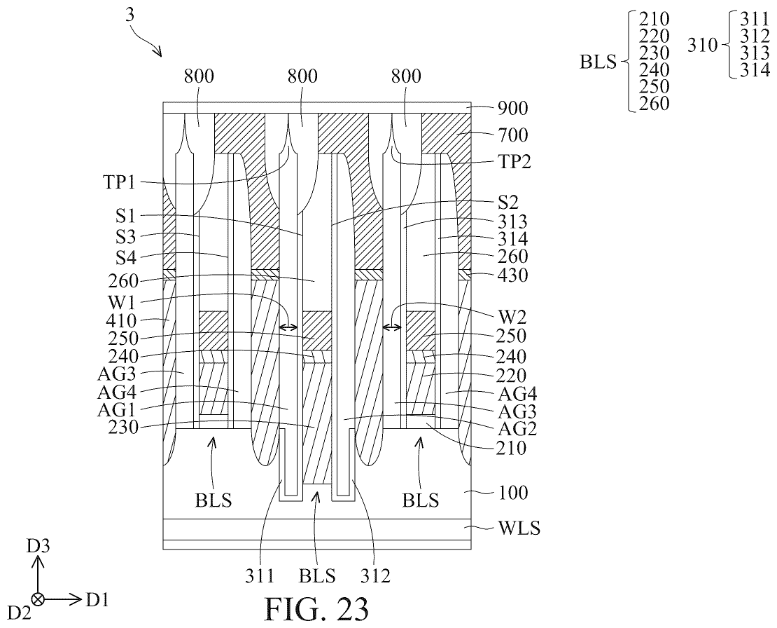

FIG. 21 shows a schematic top view of a semiconductor structure according to some embodiments. For convenience of explanation, some components may be omitted in FIG. 21. The subsequent cross-sectional views shown in FIGS. 22 and 23 may be taken along from the segment I-I′ shown in FIG. 21. As shown in FIG. 21, in the first direction D1, the second conductive pillar 700 and the bit line BL may be separated by a gap G.

FIG. 22 may be continued from FIG. 13, and the process shown in FIG. 22 may be similar to the process shown in FIG. 14. In some embodiments, as shown in FIG. 22, the protective layer 600 may be removed by passing the etchant through the opening 710 by a wet etching process such as a dilute hydrofluoric acid cleaning process. It should be noted that, since there is the gap G between the second conductive pillar 700 and the bit line BL (shown in FIG. 21), the etchant may not only remove the protective layer 600 on the first side surface S1 and the third side surface S3, but also remove the protective layer 600 on the second side surface S2 and the fourth side surface S4. Then, the etchant may not only remove the dielectric layer 500 on the first side surface S1 and the third side surface S3, but also remove the dielectric layer 500 on the second side surface S2 and the fourth side surface S4. Next, the processes shown in FIGS. 15 to 17 may be further performed to form the semiconductor structure 3.

In some embodiments, the size of the second air gap AG2 of the semiconductor structure 3 may be larger than the size of the second air gap AG2 of the semiconductor structures 1 and 2, to further reduce the parasitic capacitance. In some embodiments, the size of the fourth air gap AG4 of the semiconductor structure 3 may be larger than the size of the fourth air gap AG4 of the semiconductor structures 1 and 2, to further reduce the parasitic capacitance.

The semiconductor structures 1, 2, and/or 3 may be used as memory devices such as dynamic random access memory (DRAM), or further processes may be performed on the semiconductor structures 1, 2, and/or 3 to form memory devices such as dynamic random access memory.

In summary, the semiconductor structure of the present disclosure includes an air gap located on the side surface of the bit line structure, so as to reduce the bit line capacitance, thereby improving the reliability of the semiconductor structure. In detail, since the spacer or liner adjacent to the bit line structure will significantly affect the amount of the bit line capacitance, the present disclosure provides an air gap on the side surface (sidewall) of the bit line structure to replace spacers or liners by air gaps. Therefore, the air gap of the present disclosure may reduce the bit line capacitance. When the bit line capacitance is reduced, the bit line voltage drop of the semiconductor structure may be increased to facilitate signal sensing and avoid sense budget. For example, air gaps of the present disclosure may have different shapes to reduce bit line capacitance at different locations. For example, the semiconductor structure of the present disclosure may include an asymmetric air gap. For example, the bottom surface of the air gap may be lower than the bottom surface of the bit line structure and/or the top surface of the air gap may be higher than the top surface of the bit line structure, to more completely cover the bit line structure, thereby significantly reducing the bit line capacitance.

A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a bit line structure disposed on the substrate and having a first side surface and a second side surface opposite the first side surface;
a first liner disposed on the bit line structure and comprising a first sub-liner and a second sub-liner, wherein the first sub-liner is disposed on the first side surface, and the second sub-liner is disposed on the second side surface; and
a first air gap disposed on the first sub-liner, wherein a bottom surface of the first air gap is lower than a bottom surface of the bit line structure.

2. The semiconductor structure as claimed in claim 1, wherein a top surface of the first air gap is higher than a top surface of the bit line structure.

3. The semiconductor structure as claimed in claim 1, further comprising:
a first conductive pillar disposed on the substrate and adjacent to the bit line structure;
a second conductive pillar disposed on the first conductive pillar; and
a capping layer disposed on the bit line structure,
wherein the first liner, the first conductive pillar, the second conductive pillar, and the capping layer surround the first air gap.

4. The semiconductor structure as claimed in claim 3, wherein the first air gap is in direct contact with the first conductive pillar and the second conductive pillar.

5. The semiconductor structure as claimed in claim 1, further comprising:
a second air gap disposed on the second sub-liner, wherein a bottom surface of the second air gap is lower than the bottom surface of the bit line structure.

6. The semiconductor structure as claimed in claim 5, wherein a top surface of the second air gap is lower than a top surface of the first air gap.

7. The semiconductor structure as claimed in claim 5, further comprising:
a dielectric layer adjacent the second air gap, wherein the second air gap is disposed between the second sub-liner and the dielectric layer; and
a protective layer disposed on the dielectric layer,
wherein the second sub-liner, the dielectric layer, and the protective layer surround the second air gap.

8. The semiconductor structure as claimed in claim 7, further comprising:
a first conductive pillar disposed on the substrate and adjacent to the bit line structure, wherein the dielectric layer is disposed between the second air gap and the first conductive pillar; and
a second conductive pillar disposed on the first conductive pillar, wherein the protective layer is disposed between the second sub-liner and the second conductive pillar.

9. The semiconductor structure as claimed in claim 1, wherein a width of the first air gap decreases along a normal direction of the substrate.

10. The semiconductor structure as claimed in claim 1, wherein the first air gap has a tip portion.

11. The semiconductor structure as claimed in claim 1, wherein the bit line structure further comprises:
a bit line contact disposed on the substrate;
a bit line conductive layer disposed on the bit line contact; and
a mask layer disposed on the bit line conductive layer.

12. A method of forming a semiconductor device, comprising:
providing a substrate;
forming a bit line structure on the substrate, wherein the bit line structure has a first side surface and a second side surface opposite the first side surface;
forming a first liner on the bit line structure;
forming a first conductive pillar on the substrate, wherein the first conductive pillar is adjacent to the bit line structure;
forming a dielectric layer on the first conductive pillar; and
forming a protective layer on the dielectric layer to form a first air gap on the first side surface of the bit line structure.

13. The method as claimed in claim 12, further comprising:
forming a second conductive pillar on the first conductive pillar;
removing the protective layer and the dielectric layer on the second side surface; and
forming a capping layer on the second conductive pillar and the bit line structure to form a second air gap on the second side surface of the bit line structure.

14. The method as claimed in claim 13, further comprising:
removing the protective layer and the dielectric layer on the first side surface.

15. The method as claimed in claim 13, wherein the formation of the second conductive pillar on the first conductive pillar further comprises:
forming a conductive material on the bit line structure and the protective layer; and
removing the conductive material to form an opening in the conductive material, so as to form the second conductive pillar on the first conductive pillar, and wherein the opening exposes the protective layer on the second side surface.

16. The method as claimed in claim 15, wherein the formation of the capping layer on the second conductive pillar and the bit line structure further comprises:
forming a capping material on the second conductive pillar, the bit line structure, and the opening; and
planarizing the capping material to expose a top surface of the second conductive pillar, so as to form the capping layer on the second conductive pillar and the bit line structure.

17. The method as claimed in claim 12, further comprising:
forming a second liner on the first liner;
forming a third liner on the second liner;
forming the first conductive pillar on the substrate and on the third liner;
removing the second liner; and
etching back the first conductive pillar to form the first conductive pillar on the substrate.

18. The method as claimed in claim 17, wherein after etching back the first conductive pillar, the third liner is removed.

19. The method as claimed in claim 12, wherein the formation of the protective layer on the dielectric layer further comprises:
forming a protective material on the bit line structure, the first conductive pillar, and the dielectric layer; and
removing the protective material to expose a top surface of the first conductive pillar, so as to form the protective layer on the dielectric layer.

20. The method as claimed in claim 12, wherein the formation of the dielectric layer on the first conductive pillar further comprises:
performing a heat treatment process on the first conductive pillar to form the dielectric layer on the first conductive pillar; and
removing the dielectric layer to expose a top surface of the first conductive pillar.
